(19) United States
(12) Patent Application Publication
(10) Pub. No.: US 2011/0280093 A1
(43) Pub. Date: Nov. 17, 2011

(54) DATA PROTECTIVE STRUCTURE, ELECTRONIC DEVICE, AND METHOD OF ERASING DATA

(75) Inventor: Mikiya Takeda, Tokyo (JP)

(73) Assignee: NEC Display Solutions, Ltd., Tokyo (JP)

(21) Appl. No.: 13/138,257

(22) PCT Filed: Jan. 28, 2009
(86) PCT No.: PCT/JP2009/051312

§ 371 Date: Jul. 25, 2011

(51) Int. Cl. G11C 7/00; H05K 7/20; G06F 1/16

(52) U.S. Cl. 365/218; 361/679.57; 361/679.54

(57) ABSTRACT

The present invention includes: a circuit board which is provided with an electronic circuit part; a first case and a second case (7) that cover the electronic circuit part; a fixing screw that fixes the first case and the second case (7); a tamper switch that outputs a signal indicating that the switch member is in a first state or second state; and a cap block (11) which is attached to the second case (7) so that the tamper switch keeps the first state only when the cap block (11) covers the fixing screw.

### TECHNICAL FIELD

The present invention rerates to a data protective structure for protecting data in a semiconductor device such as a non-volatile memory, for example, an electronic device having this data protective structure, and a method of erasing data.

### BACKGROUND ART

JP10-320516A discloses a configuration for preventing unauthorized acts of reading data stored in components such as a ROM (Read-Only Memory) which is mounted on a circuit board by disassembling an electronic device. This configuration includes a case that covers components, which are mounted on the circuit board, and a plurality of fixing screws that fix this case to the circuit board, in which data stored in the components is erased when the plurality of fixing screws are unscrewed in the order different from the preset order.

In addition, for the other configurations relating to the present invention, a data protective structure is known using a switch member, a so-called tamper switch, for detecting that a case that covers components mounted on a circuit board has been removed. An example of this type of data protective structure will be described.

FIG. 1 shows a data protective structure, which is seen from the mounting surface side of a circuit board. FIG. 2 shows the data protective structure, which is seen from the soldering surface side opposite the mounting surface of the circuit board. FIG. 3 shows the mounting surface of the circuit board included in the data protective structure. FIG. 4 shows the soldering surface opposite the mounting surface of the circuit board included in the data protective structure.

As shown in FIG. 3, data protective structure 101 shown in FIG. 1 includes circuit board 103 which is provided with electronic circuit part 104 formed of various components 105, first case 106 that covers electronic circuit part 104 as shown in FIG. 1, and second case 107 that covers surface 103b (in the following, referred to as soldering surface 103b) opposite mounting surface 103a of electronic circuit part 104 as shown in FIG. 2. First case 106 is provided on the mounting surface 103a side of circuit board 103, and is fixed to circuit board 103 with fixing screws 109. Similarly, second case 107 is provided on the soldering surface 103b side, and is fixed to circuit board 103 with fixing screws 109.

Then, this data protective structure 101 includes a plurality of tamper switches 108 for detecting that first case 106 or second case 107 has been removed from circuit board 103. Moreover, electronic circuit part 104 is provided with eraser circuit 110 that erases data in electronic circuit part 104 based on the result detected by tamper switches 108.

As shown in FIGS. 3 and 4, tamper switches 108 are mounted on mounting surface 103a and soldering surface 103b of circuit board 103, and disposed at a plurality of places. Tamper switch 108 has operator 108a that is pressed by first case 106 and second case 107. Eraser circuit 110 is mounted on mounting surface 103a of circuit board 103, which is included in components 105.

In data protective structure 101 which is configured as described above, in the case of reading data in components 105 on circuit board 103, fixing screws 109 are unscrewed and first case 106 or second case 107 is removed from circuit board 103. When first case 106 or second case 107 is removed from circuit board 103, the pressed state of operator 108a, which has been pressed by first case 106 or second case 107, is released in tamper switch 108. Thus, tamper switch 108 detects that first case 106 or second case 107 has been removed from circuit board 103. Then, based on the detected result of tamper switch 108, eraser circuit 110 erases data in components 105 on electronic circuit part 104.

### DISCLOSURE OF THE INVENTION

Now, in the aforementioned data protective structure, the fixing screws fixing the second case are loosened and the second case is moved with respect to the circuit board, resulting in possibly causing a gap between the circuit board and the second case.

More specifically, as shown in FIG. 5, a small gap is provided between second case 107 and soldering surface 103b of circuit board 103, at the position indicated by arrow C, for example, by separating second case 107 from circuit board 103 within the range at which operator 108a of tamper switch 108 continues to be pressed by case 107, so that an electrical connection can be established to given component 105 from the soldering surface 103b side of circuit board 103 through this gap.

As a result, data protective structure 101 mentioned above has a problem in which it is likely that data is read before tamper switch 108 detects that second case 107 has been moved with respect to circuit board 103 and that data in electronic circuit part 104 has been erased by eraser circuit 110, resulting in poor reliability of protecting data.

It is an objet of the present invention to provide a data protective structure that can improve the reliability of protecting data in an electronic circuit part, an electronic device having this data protective structure, and a method of erasing data.

A data protective structure according to the present invention includes: a circuit board which is provided with an electronic circuit part; a case member which covers the electronic circuit part; a fastening member which fixes the case member; a switch member which outputs a signal indicating that the switch member is in a first state or second state; and a cap member which is attached to the case member so that the switch member keeps the first state only when the cap member covers the fastening member.

Moreover, an electronic device according to the present invention includes: the data protective structure according to the present invention; and an eraser circuit which erases data in the electronic circuit part when the switch member is in the second state.

Furthermore, a method of erasing data according to the present invention using a data protective structure including a circuit board which is provided with an electronic circuit part, a case member which covers the electronic circuit part, a fastening member which fixes the case member, a switch member which outputs a signal indicating that the switch member is in a first state or second state, and a cap member which is attached to the case member so that the switch member keeps the first state only when the cap member covers the fastening member, the method includes: erasing data in said electronic circuit part by an eraser circuit when said switch member is in said second state.

In addition, the electronic circuit part in the present invention is meant to include both the mounting surface side on which the components are mounted on the circuit board and the surface opposite this mounting surface. Because of this, the data protective structure according to the present invention includes a configuration in which the case member that covers the electronic circuit part is provided on the circuit board so as to cover at least the mounting surface of the circuit board or the surface opposite this mounting surface.

According to the present invention, in the case when the case member has been removed from the circuit board, it is necessary to remove the cap member from the case member in order to loosen the fastening member that fixes the case member. Thus, in the present invention, it is possible to erase data in the electronic circuit part when the cap member has been moved with respect to the case member without loosening the fastening member, so that it is possible to improve the reliability of protecting data.

### BRIEF DESCRIPTION OF THE DRAWINGS

FIG. 1 is a perspective view illustrating a data protective structure relating to the present invention, which is seen from the mounting surface side of a circuit board;

FIG. 2 is a perspective view illustrating the data protective structure relating to the present invention, which is seen from the soldering surface side opposite the mounting surface of the circuit board;

FIG. 3 is a perspective view illustrating the mounting surface of the circuit board included in the data protective structure relating to the present invention;

FIG. 4 is a perspective view illustrating the soldering surface opposite the mounting surface of the circuit board included in the data protective structure relating to the present invention;

FIG. 5 is a side view illustrative of a problem of the data protective structure relating to the present invention;

FIG. 6 is a perspective view illustrating a data protective structure according to an embodiment, which is seen from the mounting surface side of a circuit board;

FIG. 7 is a perspective view illustrating the mounting surface of the circuit board included in the data protective structure according to an embodiment;

FIG. 8 is a perspective view illustrating the inner surface side of a first case according to an embodiment;

FIG. 9 is a perspective view illustrating the data protective structure according to an embodiment, which is seen from the soldering surface side opposite the mounting surface of the circuit board;

FIG. 10 is a perspective view illustrating the state in which cap blocks are removed from a second case according to an embodiment;

FIG. 11 is a plan view illustrating a mounting recessed part of the second case according to an embodiment;

FIG. 12A is a perspective view illustrating a cap block according to an embodiment;

FIG. 12B is a perspective view illustrating the cap block according to an embodiment;

FIG. 12C is a perspective view illustrating the reverse side of the cap block according to an embodiment;

FIG. 12D is a perspective view illustrating the reverse side of the cap block according to an embodiment;

FIG. 13 is a plan view illustrating the second case and the cap blocks fixed to the circuit board;

FIG. 14 is a cross sectional view illustrating the state of mounting the cap block along line A-A in FIG. 13;

FIG. 15 is a cross sectional view illustrating the state of mounting the cap block along line B-B in FIG. 13; and

FIG. 16 is a schematic diagram illustrating a projector according to an embodiment.

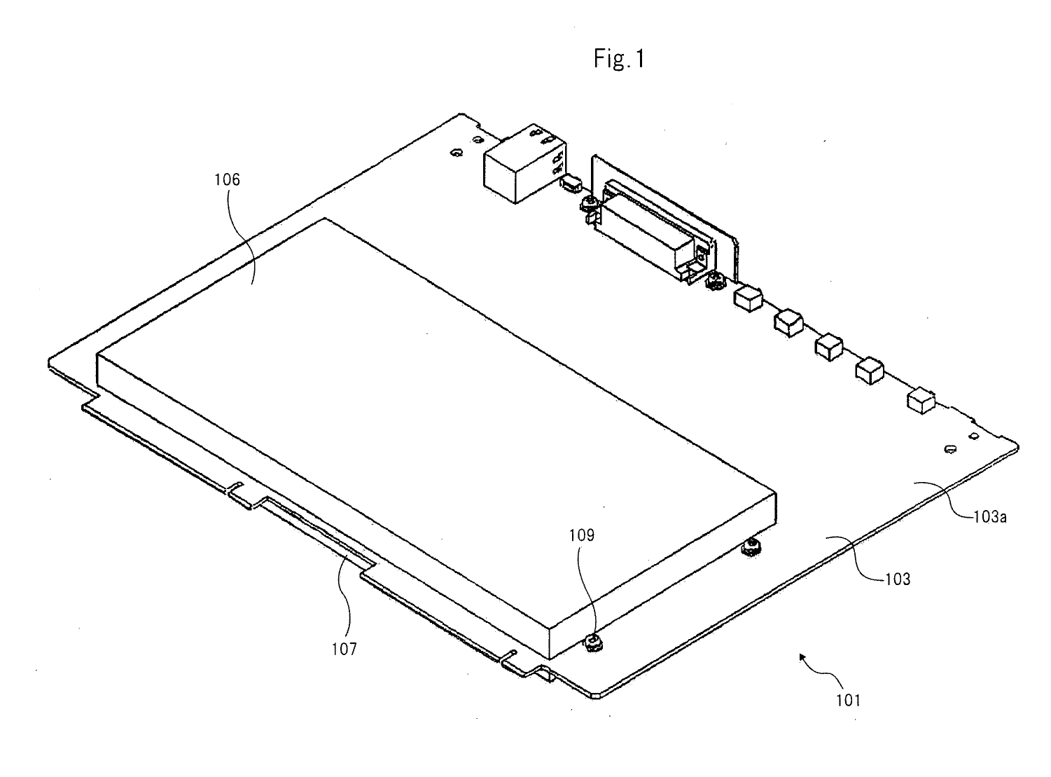

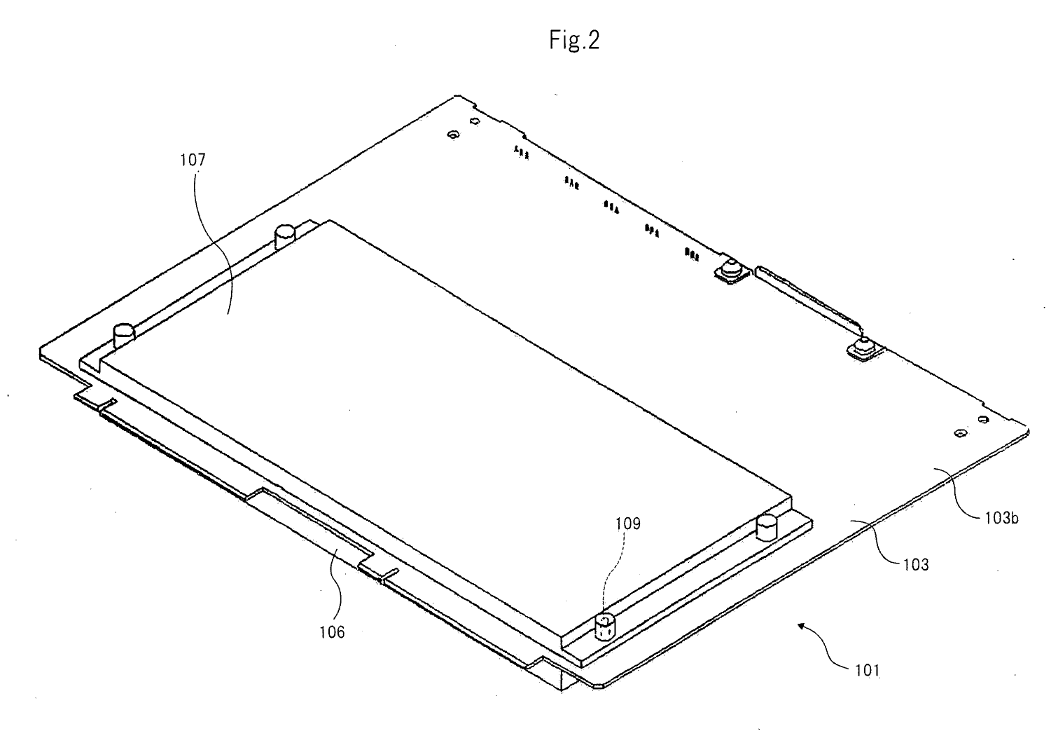

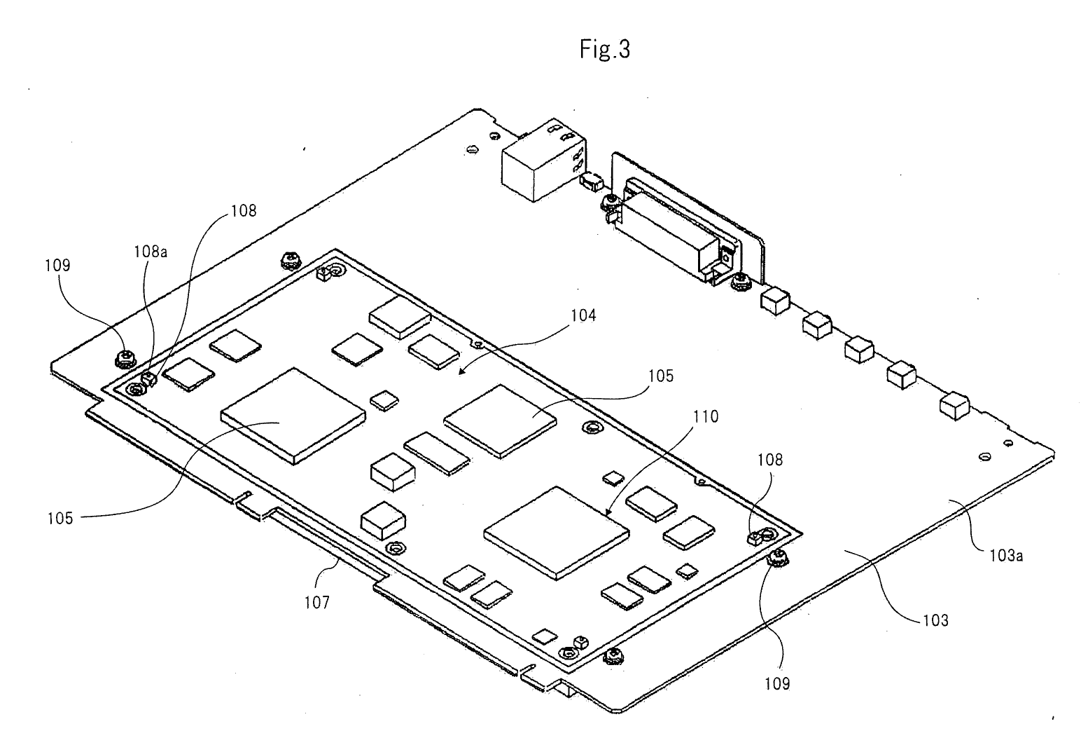

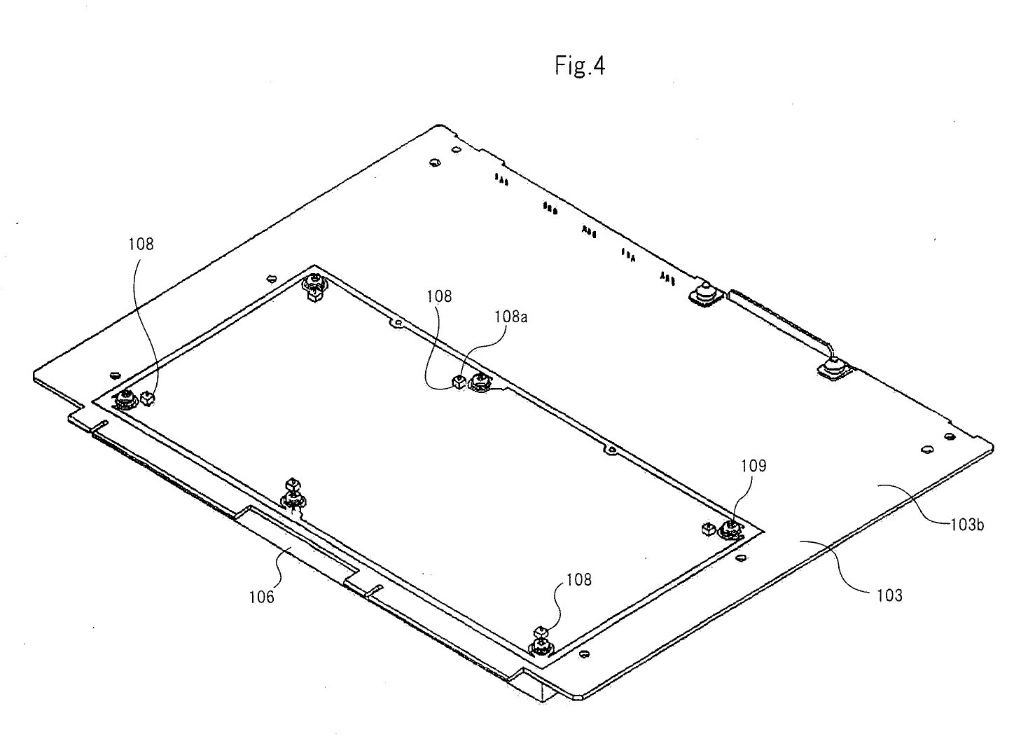

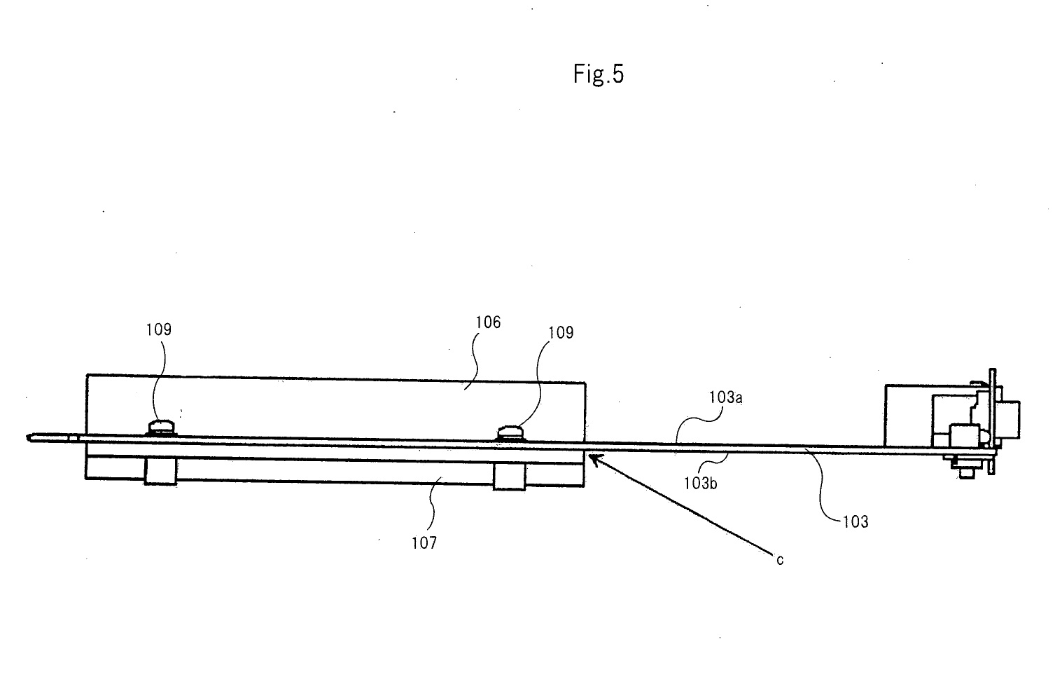

### BEST MODE FOR CARRYING OUT THE INVENTION

In the following, a specific embodiment of the present invention will be described with reference to the drawings.

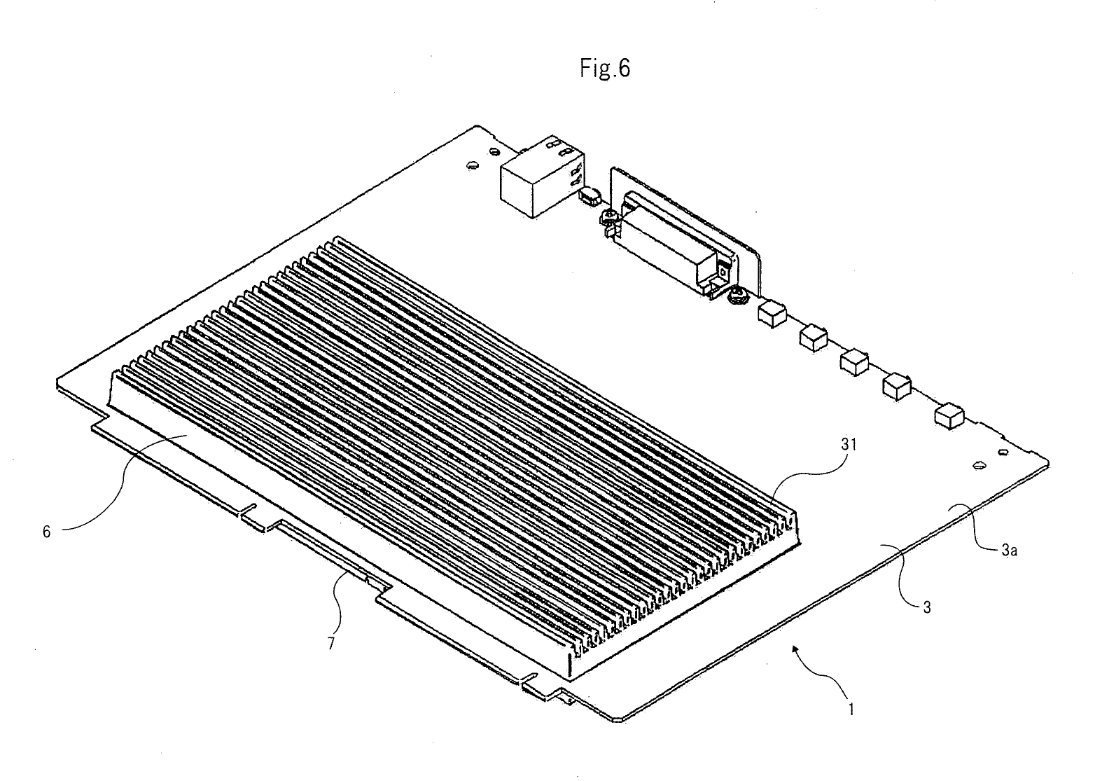

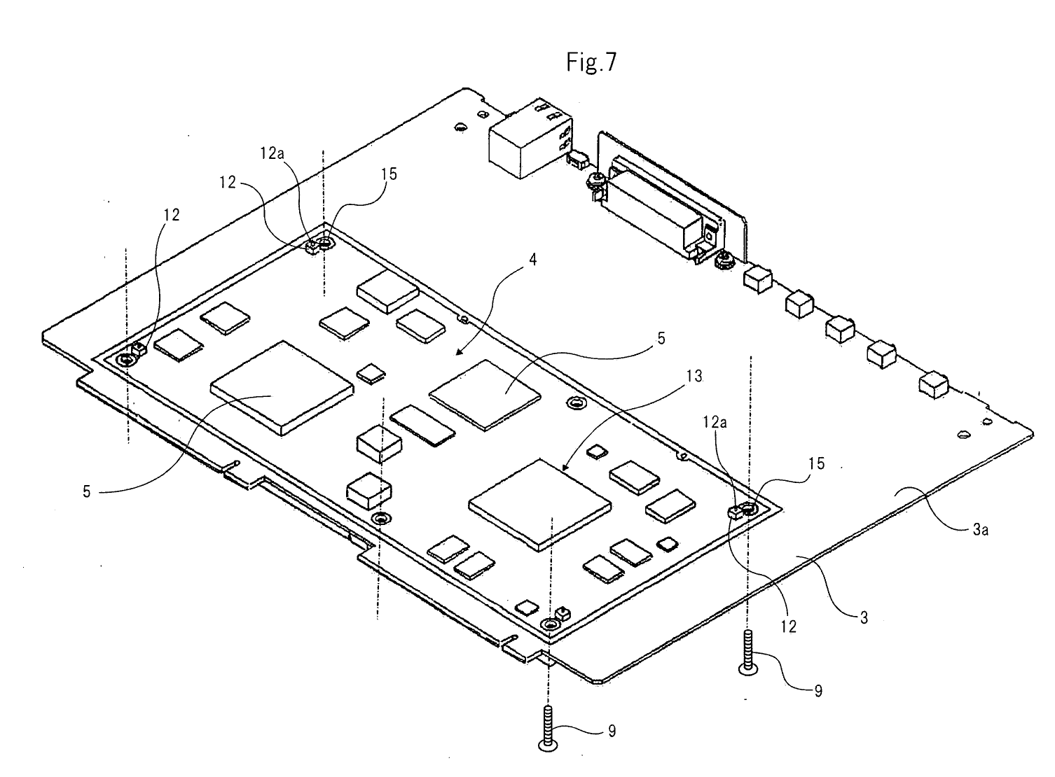

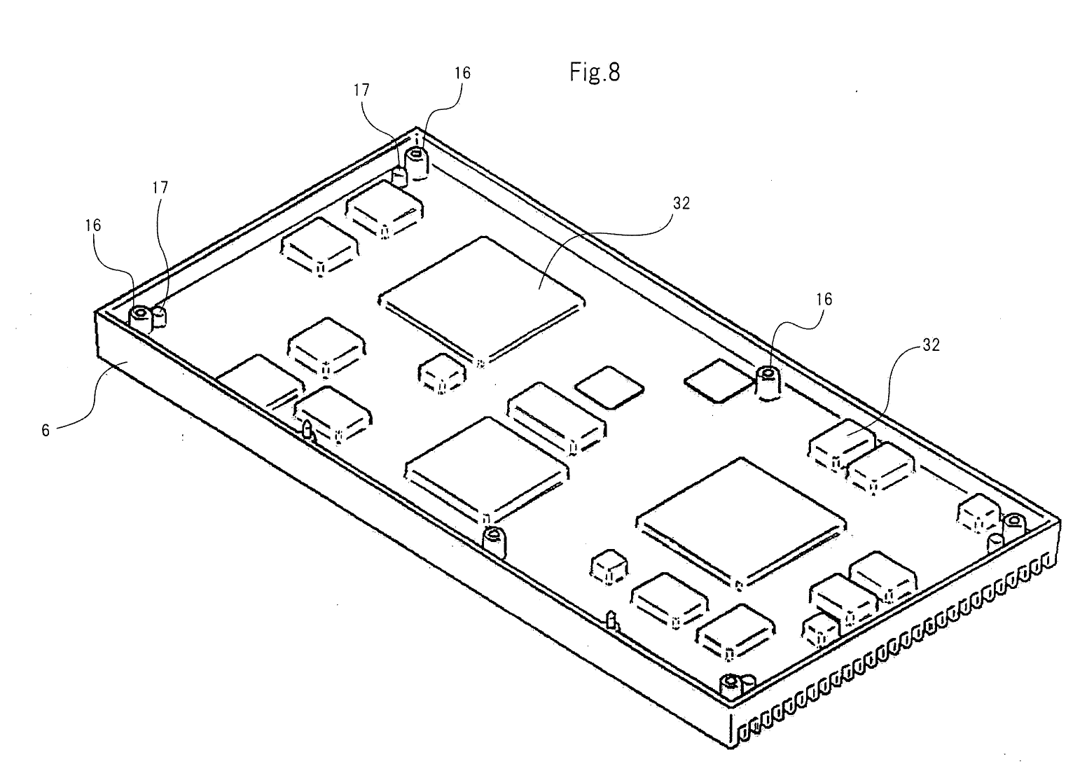

FIG. 6 shows a data protective structure according to an embodiment, which is seen from the mounting surface side of a circuit board. FIG. 7 shows the mounting surface of the circuit board included in the data protective structure according to this embodiment. FIG. 8 shows the inner surface side of a first case according to this embodiment. FIG. 9 shows the data protective structure according to this embodiment, which is seen from the soldering surface side opposite the mounting surface of the circuit board.

As shown in FIGS. 6 and 7, data protective structure 1 according to this embodiment includes circuit board 3 which is provided with electronic circuit part 4 formed of various components 5, first case 6 as a case member that covers components 5 on electronic circuit part 4, second case 7 as another case member that covers soldering surface 3b opposite mounting surface 3a of electronic circuit part 4, and a plurality of fixing screws 9 as fastening members that fix each of cases 6 and 7 to circuit board 3 in the state in which first case 6 and second case 7 cover the mounting surface 3a side and the soldering surface 3b side of electronic circuit part 4.

Moreover, as shown in FIGS. 7 and 9, this data protective structure 1 includes cap block 11 as a cap member that is attached to second case 7 to cover fixing screw 9, and tamper switch 12 as a switch member that detects that this cap block 11 has been moved with respect to second case 7. Furthermore, electronic circuit part 4 is provided with eraser circuit 13 that erases data in electronic circuit part 4 based on the detected result by tamper switch 12.

As shown in FIG. 7, circuit board 3 has screw hole 15 into which fixing screw 9 is inserted. A plurality of tamper switches 12, which are pressed by first case 6, are each provided at the position next to screw hole 15 in mounting surface 3b of circuit board 3. Tamper switch 12 has operator 12a that is pressed by first case 6, and outputs, in order to eraser circuit 13, a signal indicating that tamper switch 12 is in a first state or second state according to the pressed state of operator 12a.

Moreover, eraser circuit 13 is mounted on mounting surface 3a of circuit board 3. Furthermore, the plurality of tamper switches 12, each of which is pressed by cap block 11, not shown, are provided on soldering surface 3b of circuit board 3. These tamper switches 12 have operator 12a that is pressed by cap block 11.

As shown in FIG. 6, first case 6 is provided on mounting surface 3a of circuit board 3 to cover various components 5 mounted on circuit board 3. Moreover, a plurality of screw hole parts 16, to each of which fixing screw 9 is fastened, are provided on the inner surface of first case 6, and fixing screw 9 fastened from the outside of second case 7 is fastened to screw hole part 16 through screw hole 15 in circuit board 3. Furthermore, a plurality of contact parts 17 are each provided at the position next to screw hole part 16 on the inner surface of first case 6, with contact part 17 pressing operator 12a of each tamper switch 12 which is provided on mounting surface 3a of circuit board 3.

As shown in FIGS. 7 and 9, second case 7 is provided on soldering surface 3b of circuit board 3 to cover the soldering portions of components 5. These first case 6 and second case 7 have the same area to cover circuit board 3, which are joined to each other and fixed to circuit board 3 with fixing screws 9.

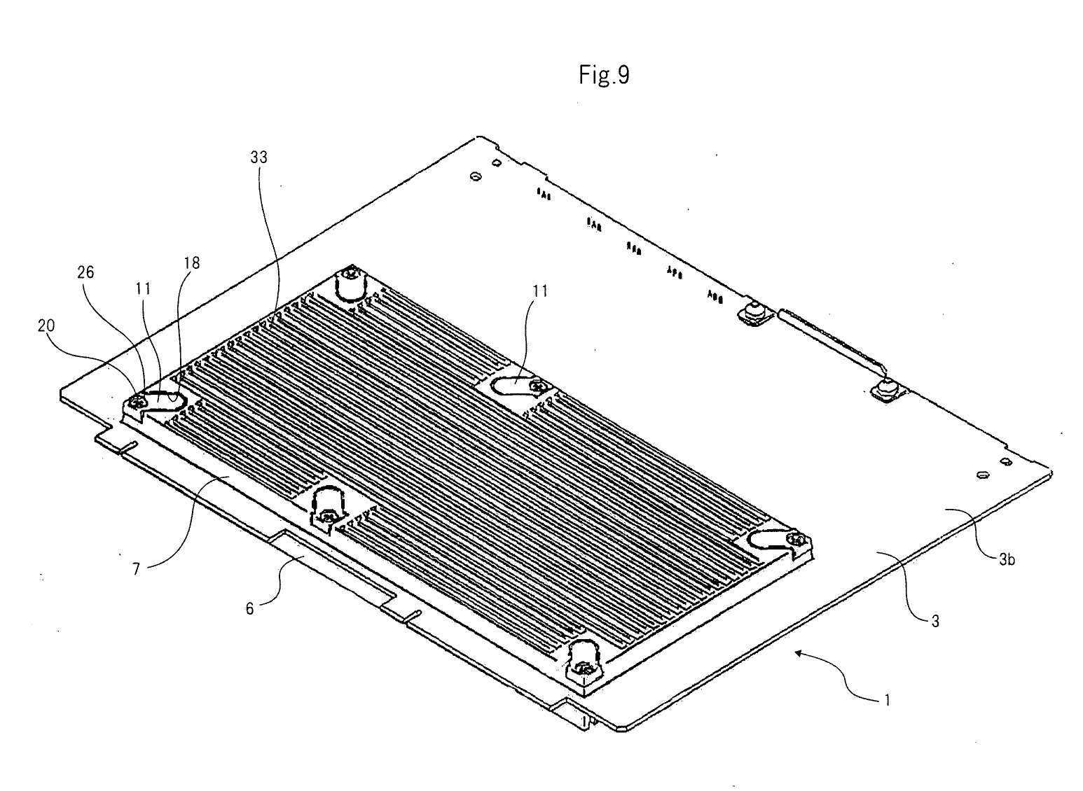

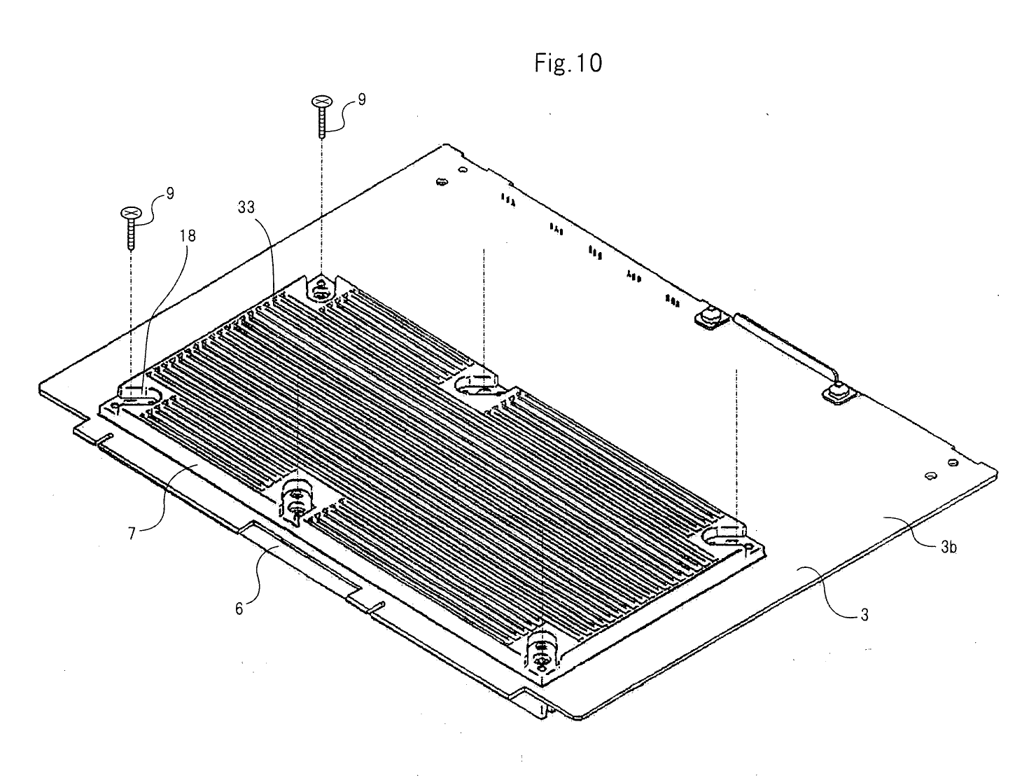

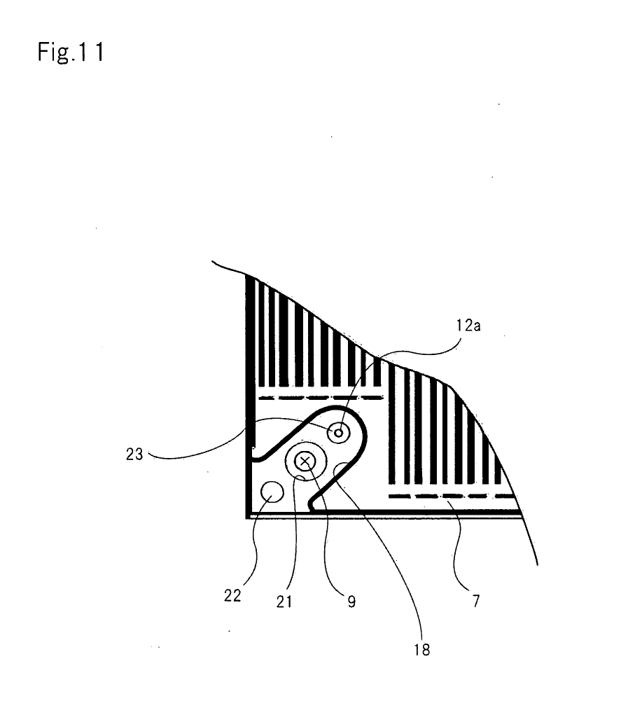

FIG. 10 shows the state in which cap blocks 11 are removed from second case 7 in this embodiment. FIG. 11 shows a mounting recessed part of second case 7 in this embodiment.

In addition, as shown in FIG. 10, second case 7 is formed with a plurality of mounting recessed parts 18, to each of which cap block 11 is fitted. These mounting recessed parts 18 are formed in the same shape, to which cap block 11 in the same shape, can be attached.

As shown in FIGS. 10 and 11, there are provided on the underside of mounting recessed part 18, screw hole 21 to which fixing screw 9 is fastened, screw hole 22, to which fixing screw 20 is fastened to fix cap block 11 to second case 7, and through hole 23, into which operator 12a of tamper switch 12 which is provided on soldering surface 3b of circuit board 3 is inserted.

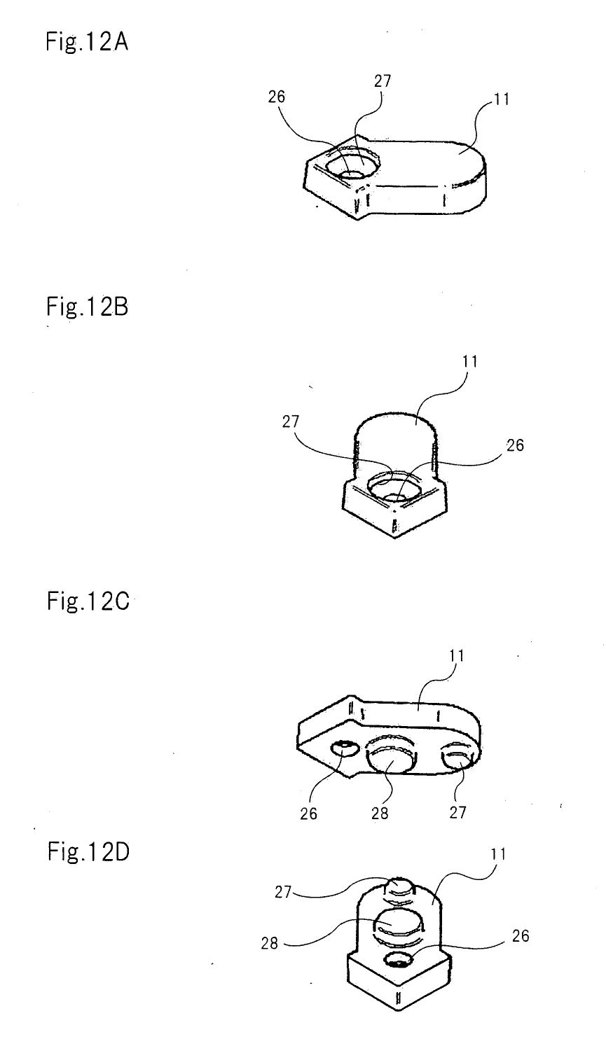

Cap block 11 is shown in FIGS. 12A to 12D. As shown in FIG. 9 and FIGS. 12A to 12D, cap block 11 has screw hole 26 to which fixing screw 20 is fastened. This screw hole 26 is formed with recessed part 27 into which the head of fixing screw 20 is accommodated. In addition, contact part 27 that presses operator 12a of tamper switch 12 and cap part 28 that covers the head of fixing screw 9 are integrally provided in a protruding manner on the reverse side of cap block 11, the reverse side being placed on the underside of mounting recessed part 18.

Cap block 11 is attached to mounting recessed part 18 of second case 7 in such a way that tamper switch 12 keeps the first state only when cap block 11 covers fixing screw 9. When cap block 11 has been removed from mounting recessed part 18 of second case 7, tamper switch 12 is brought into the second state, and tamper switch 12 outputs the signal indicating the second state to eraser circuit 13. As a result of this, eraser circuit 13 erases data in electronic circuit part 4. More specifically, eraser circuit 13 erases data in electronic circuit part 4 when tamper switch 12 is in the second state.

In addition, cap block 11 is fitted to mounting recessed part 18, so that it is possible to readily and individually position contact part 27 and cap part 28 of cap block 11 to screw holes 21 and 22 and through hole 23 of mounting recessed part 18.

Cap block 11 that is fitted to mounting recessed part 18 of second case 7 is fixed with fixing screw 20. The state of cap block 11 that is fixed to mounting recessed part 18 will be described with reference to the drawings.

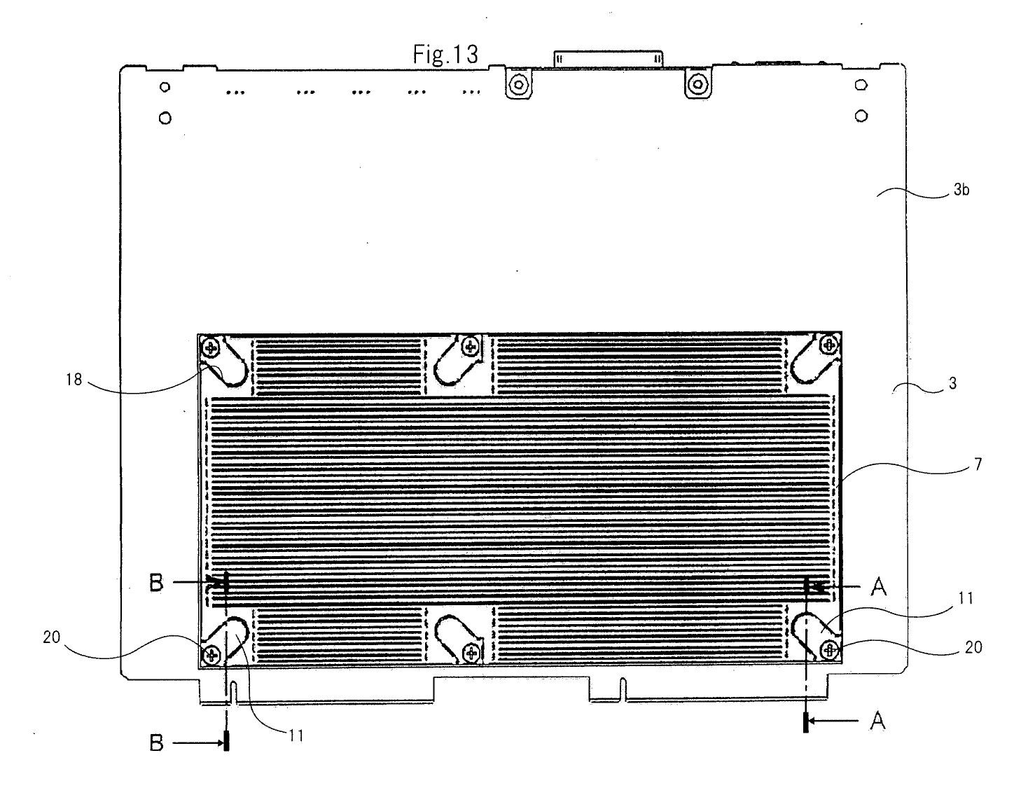

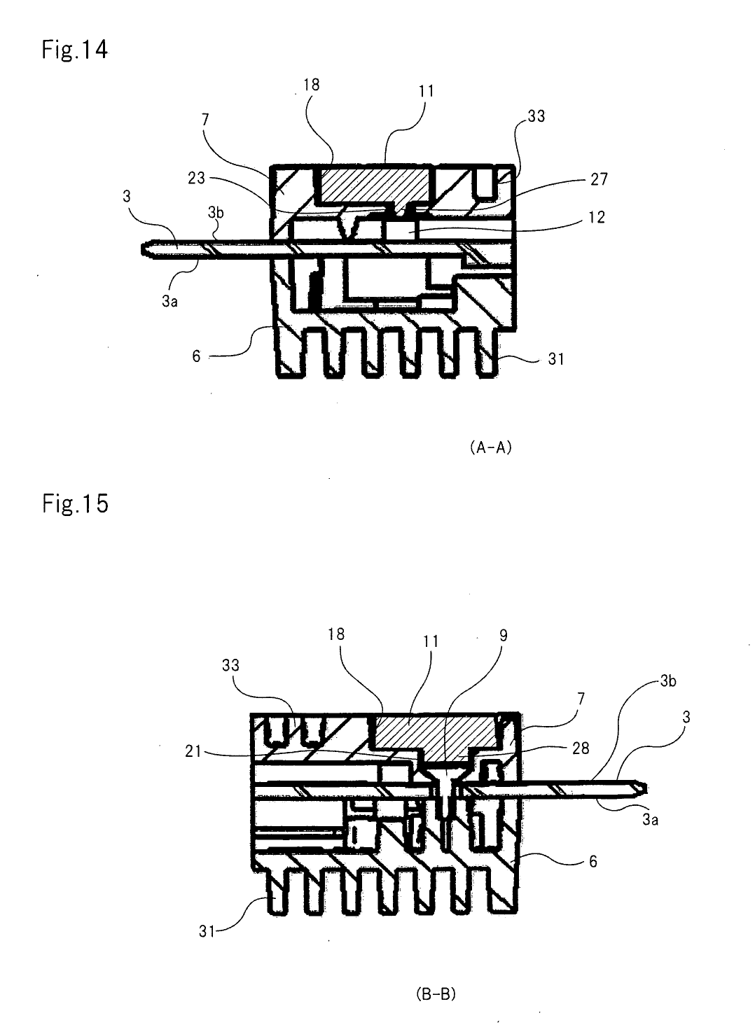

FIG. 13 is a plan view illustrating the state in which cap blocks 11 are fixed to mounting recessed parts 18 of second case 7. FIG. 14 is a cross sectional view along line A-A in FIG. 13. FIG. 15 is a cross sectional view along line B-B in FIG. 13.

As shown in FIGS. 13 and 14, contact part 27 of cap block 11 is inserted into through hole 23 to press operator 12a of tamper switch 12 which is provided on soldering surface 3b of circuit board 3 in the state in which cap block 11 is fixed to mounting recessed part 18 of second case 7.

According to this configuration, it is possible to reliably press operator 12a of tamper switch 12 by block 11. Moreover, in this configuration, it is difficult to shift the position of cap block 11 with respect to mounting recessed part 18 with operator 12a of tamper switch 12 continuing to be pressed by contact part 27 of cap block 11, so that it is possible to improve safety from the unauthorized removal of cap block 11.

Furthermore, as shown in FIGS. 13 and 15, cap part 28 of cap block 11 is inserted into screw hole 21 to make contact with the head of fixing screw 9 in the state in which cap block 11 is fixed to mounting recessed part 18 of second case 7.

According to this configuration, it is possible to reliably cover the head of fixing screw 9 with cap block 11. Moreover, in this configuration, it is difficult to shift the position of cap block 11 with respect to mounting recessed part 18 with tamper switch 12 continuing to be pressed by cap block 11 so that it is possible to improve safety from the unauthorized removal of cap block 11.

In addition, in this embodiment, a configuration is adopted such that cap block 11 is fitted into mounting recessed part 18. Thus, as similar to the aforementioned effect, it is difficult to shift the position of cap block 11 with respect to mounting recessed part 18 with the condition in which tamper switch 12 continues to be pressed, so that it is possible to improve safety from the unauthorized removal of cap block 11.

In addition to the aforementioned configurations, as shown in FIGS. 6 and 8, a plurality of heat radiating fins 31 are formed on the outer side of first case 6 in this embodiment, which are a heat dissipation part that dissipates heat generated in various components 5 mounted on mounting surface 3a of circuit board 3 to the outside of first case 6. Moreover, a plurality of contact parts 32 are each formed at the position corresponding to each of components 5 on the inner surface of first case 6, which are a thermal conducting part to which heat is conducted from various components 5. Each contact part 32 is formed in a predetermined amount of projection corresponding to individual components 5.

Similarly, as shown in FIG. 9, second case 7 is also provided with a plurality of heat radiating fins 33, which are heat dissipation parts that dissipate heat generated in components 5 on circuit board 3 to the outside of second case 7. In addition, although not shown in the drawing, such a configuration is preferable in which a thermal conductive sheet with insulating properties be provided between contact part 32 and component 5, which can improve the insulating properties and thermal conductivity of first case 6.

According to this configuration, it is possible to dissipate heat generated in components 5 on circuit board 3 from heat radiating fins 31 to the outside through contact parts 32 of first case 6 and to dissipate heat from heat radiating fins 33 of second case 7 to the outside. Because of this, it is possible to improve the operational reliability of electronic circuit part 4 of circuit board 3.

For data protective structure 1 which is configured above, the operation of erasing data in electronic circuit part 4 will be described.

First, in order to read data in electronic circuit part 4 of data protective structure 1 according to this embodiment, it is necessary to loosen fixing screws 9 that fix first and second cases 6 and 7 to circuit board 3 to move first case 6 or second case 7 from circuit board 3. However, in this embodiment, because fixing screw 9 is covered with cap block 11, it is necessary to remove cap block 11 from mounting recessed part 18 of second case 7 in order to loosen fixing screw 9.

However, in data protective structure 1, when fixing screw 20 that fixes cap block 11 to second case 7 is loosened to move cap block 11 with respect to second case 7, tamper switch 12 detects that cap block 11 has been moved. Because of this, when cap block 11 has been removed from mounting recessed part 18 to expose the head of fixing screw 9, tamper switch 12 detects that second case 7 is being removed from circuit board 3. Thus, in this embodiment, eraser circuit 13 erases data in electronic circuit part 4 before second case 7 has been moved with respect to circuit board 3 without loosening fixing screw 9 at all.

In addition, in this embodiment, when first case 6 is detached from circuit board 3 by some unpredictable scheme, the pressed state of operator 12a of tamper switch 12 which is provided on mounting surface 3a of circuit board 3 is released. Thus, also when tamper switch 12 detects that first case 6 has been moved, eraser circuit 13 erases data in electronic circuit part 4.

In addition, in a method of erasing data according to this embodiment using data protective structure 1 mentioned above, eraser circuit 13 erases data based on the detected result of tamper switch 12 which detects that cap block 11 has been moved with respect to second case 7. In other words, in this method of erasing data, eraser circuit 13 erases data when tamper switch 12 is in the second state.

As described above, in accordance with data protective structure 1 according to this embodiment, tamper switch 12 detects that cap block 11 has been moved with respect to second case 7, so that it is possible to detect that second case 7 has been being removed before fixing screw 9 that fixes second case 7 to circuit board 3 is loosened. Accordingly, in this data protective structure 1, it is possible to improve the reliability of circuit board 3 to protect data in electronic circuit part 4.

Moreover, because first case 6 and second case 7 are joined to each other and fixed to circuit board 3 with fixing screws 9, it is possible to individually protect mounting surface 3a and soldering surface 3b of circuit board 3 using tamper switch 12 that detects that cap block 11 has been moved.

Furthermore, because contact part 27 and cap part 28 are individually formed in a protruding manner in cap block 11, it is possible to keep the state in which cap part 28 covers the head of fixing screw 9 while contact part 27 keeps pressing operator 12a of tamper switch 12, even though cap block 11 has been lifted from mounting recessed part 18. Thus, according to this configuration, it is possible to further improve the reliability of protecting data.

In addition, in the aforementioned embodiment, a configuration is adopted such that first and second cases 6 and 7 are fixed to circuit board 3 with fixing screws 9. However, the present invention is not limited to this configuration, which may adopt such a configuration in which the first and second case are fixed to other constituent members such as a chassis or frame that supports the circuit board, for example. Also in the case of adopting this configuration, it is possible to erase data by the eraser circuit before the fixing screw is loosened by detecting that the cap block has been moved with respect to the second case.

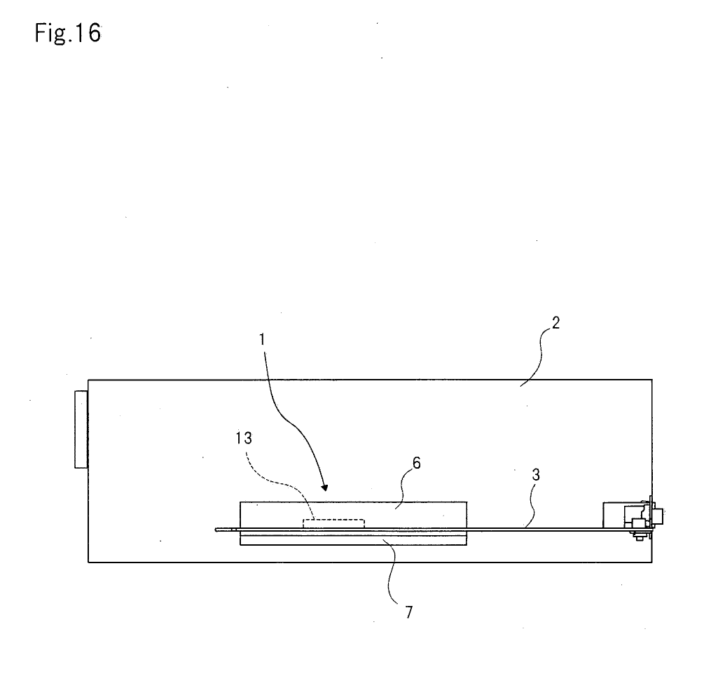

FIG. 16 shows a projector according to an embodiment. Data protective structure 1 thus configured is preferably used in various electronic devices such as projector 2 that projects images on the projection surface as shown in FIG. 16, for example. This projector 2 includes aforementioned data protective structure 1, and eraser circuit 13 mounted on circuit board 3. Moreover, it is also possible to adapt the data protective structure to an expansion board or the like, the expansion board being formed to have various semiconductor devices mounted on a circuit board, for example, and being mounted on an electronic device. Furthermore, it is also possible to adapt the present invention to a memory cartridge or the like, for example, as long as the memory cartridge is configured to include a circuit board which is provided with an electronic circuit part and a case that covers the electronic circuit part of the circuit board.

As discussed above, the present invention has been described with reference to the embodiment. However, the present invention is not limited to the forgoing embodiment. The configuration and detail of the present invention can be variously modified in a manner that a person skilled in the art can appreciate the modifications within the scope of the present invention.

1. A data protective structure comprising:
a circuit board which is provided with an electronic circuit part;
a case member which covers said electronic circuit part;
a fastening member which fixes said case member;
a switch member which outputs a signal indicating that said switch member is in a first state or second state; and
a cap member which is attached to said case member so that said switch member keeps said first state only when said cap member covers said fastening member.

2. The data protective structure according to claim 1, comprising another case member which covers a surface of said circuit board opposite a surface covered with said case member,
wherein said case member and said another case member are joined to each other with said fastening member, and said case member and said another case member are fixed to said circuit board.

3. The data protective structure according to claim 1, wherein:
said switch member has an operator pressed by said cap member; and
said cap member is provided with a contact part which presses said operator, and said contact part protrudes from said cap member.

4. The data protective structure according to claim 3,
wherein said cap member is provided with a cap part which covers said fastening member, and said contact part protrudes from said cap member.

5. The data protective structure according to claim 1,
wherein said case member has a recessed part into which said cap member is fitted.

6. The data protective structure according to claim 1,
wherein said case member has:
a thermal conducting part that is in contact with a component included in said electronic circuit part, wherein heat is conducted from the component to said thermal conducting part; and
a heat dissipation part which dissipates the heat which is conducted from said thermal conducting part to an outside of said case member.

7. An electronic device comprising:
the data protective structure according to claim 1; and
an eraser circuit which erases data in said electronic circuit part when said switch member is in said second state.

8. A method of erasing data using a data protective structure including a circuit board which is provided with an electronic circuit part, a case member which covers said electronic circuit part, a fastening member which fixes said case member, a switch member which outputs a signal indicating that said switch member is in a first state or second state, and a cap member which is attached to said case member so that said switch member keeps said first state only when said cap member covers said fastening member, the method comprising:
erasing data in said electronic circuit part by an eraser circuit when said switch member is in said second state.
